(19) United States
(12) Patent Application Publication
(10) Pub. No.: US 2025/0273534 A1
(43) Pub. Date: Aug. 28, 2025

(54) GALLIUM NITRIDE HIGH ELECTRON MOBILITY TRANSISTOR AND METHOD FOR MANUFACTURING THE SAME

(71) Applicant: Infinity Communication Tech. Inc., Hsinchu City (TW)

(72) Inventors: Shang-Hua TSAI, Hsinchu City (TW); Guang-Rong YOU, Hsinchu City (TW)

(21) Appl. No.: 18/819,903

(22) Filed: Aug. 29, 2024

(30) Foreign Application Priority Data
Feb. 22, 2024 (TW) 113106314

(51) Int. Cl. H01L 23/373; H01L 29/20; H01L 29/66; H01L 29/778

(52) U.S. Cl. CPC H01L 23/3736; H10D 30/015; H10D 30/475; H10D 62/8503

(57) ABSTRACT

A gallium nitride high electron mobility transistor includes a transistor structure, a heat dissipation structure for dissipating heat generated by the transistor structure, and at least one conductive structure. The transistor structure includes a composite semiconductor unit and an electrode unit. The composite semiconductor unit includes a gallium nitride layer. The heat dissipation structure includes a heat dissipation insulating layer and a heat dissipation metal unit. The heat dissipation metal unit includes a molybdenum substrate. The heat dissipation structure and the transistor structure cooperatively define at least one channel penetrating from a side of the heat dissipation insulating layer to the electrode unit. The conductive structure is disposed in the channel, and has two opposite ends respectively electrically connected to the heat dissipation metal unit and the electrode unit. A method for manufacturing a gallium nitride high electron mobility transistor is also provided.

### CROSS-REFERENCE TO RELATED APPLICATION

This application claims priority to Taiwanese Invention patent Application No. 11/310,6314, filed on Feb. 22, 2024, the entire disclosure of which is incorporated by reference herein.

### FIELD

The disclosure relates to a power semiconductor device and a method for manufacturing the same, and more particularly to a gallium nitride high electron mobility transistor and a method for manufacturing the same.

### BACKGROUND

A gallium nitride (GaN) high electron mobility transistor (HEMT) is a representative of wide band-gap (WBG) power semiconductor device, and has a great potential in high-frequency power applications. In general, the GaN HEMT is a horizontal device, and electrode structures thereof, such as a gate electrode, a drain electrode, and a source electrode, are formed on a single-crystal GaN semiconductor layer. A breakdown voltage threshold of the GaN HEMT not only increases with an increase of a horizontal distance between the gate electrode and the drain electrode, but also is affected by a thickness of the single-crystal GaN semiconductor layer in a vertical direction if the single-crystal GaN semiconductor layer is grown in a heteroepitaxial manner on a conductive substrate made of, for example, single-crystal silicon (Si). That is to say, the breakdown voltage threshold depends on the electrode design and epitaxial thickness.

Since production of a single-crystal GaN substrate is yet to be refined, and the single-crystal GaN can only be epitaxially grown on a material that also has a single-crystal structure, the single-crystal GaN is usually crystallized on a single-crystal silicon carbide (SiC) substrate, a single-crystal Si substrate, or a single-crystal sapphire substrate in the heteroepitaxial manner, so as to form a composite semiconductor substrate having the single-crystal GaN. Although applying a semiconductor substrate, which includes a single-crystal semi-insulating SiC substrate and a single-crystal GaN layer epitaxially crystallized on the single-crystal semi-insulating SiC substrate and merely having an epitaxial thickness of 0.4 μm, to the GaN HEMT allows the GaN HEMT to attain a breakdown voltage of approximately 1700 V, due to high cost of the single-crystal semi-insulating SiC substrate, current commercial application of such semiconductor substrate is limited in the field of radio frequency (RF) that requires high performance. There are no reports on the commercial application of the semiconductor substrate in the power source field.

Moreover, even though use of another semiconductor substrate, which is made by epitaxially forming a single-crystal GaN layer on a single-crystal Si substrate, in the GaN HEMT may be more economical because the single-crystal Si substrate is cheaper than the single-crystal SiC substrate, due to a limited conductivity of the single-crystal Si substrate, the single-crystal GaN layer is required to have an epitaxial thickness of at least 5.0 μm to allow a breakdown voltage of the GaN HEMT to be close to 650 V. In addition, because a difference in thermal expansion coefficient between GaN and Si is increased up to 50%, a superlattice structure of aluminum nitride (AlN)/GaN is usually added during epitaxy process of the GaN, resulting in an increase in epitaxy time of the single-crystal GaN on the single-crystal Si substrata, and high cost of the semiconductor substrate. Thus, the semiconductor substrate is gradually unsuitable for commercial manufacturing of the GaN HEMT.

However, when still another semiconductor substrate, which is made by epitaxially forming a single-crystal GaN on a single-crystal sapphire substrate, is used in the GaN HEMT, such GaN HEMT can attain a breakdown voltage of close to 650 V when an epitaxial thickness of the single-crystal GaN is merely 2.5 μm (i.e., thinner than the epitaxial thickness thereof on the single-crystal Si substrate). Additionally, the single-crystal sapphire substrate is cheaper than the single-crystal SiC substrate. Therefore, in a conventional GaN HEMT, a heterostructure made by epitaxially crystallizing the single-crystal GaN on the single-crystal sapphire substrate usually serves as a semiconductor substrate.

Nevertheless, a thermal conductivity of the single-crystal sapphire substrate (0.47 W/cmK) is lower than that of the single-crystal SiC substrate (4.5 W/cmK) and that of the single-crystal Si substrate (1.5 W/cmK), causing a problem of overheating during operation of such conventional GaN HEMT.

Besides, a drain electrode of a conventional power Si metal-oxide-semiconductor field-effect transistor (MOSFET) is usually designed to be positioned on a backside thereof, and in order to reduce high-frequency parasitic inductance, a source electrode of a conventional RF device is also designed to be on a backside thereof. Accordingly, how to guide the drain electrode or the source electrode of the GaN HEMT to a backside thereof, so that the GaN HEMT is able to be packaged in a same traditional way as that of the conventional power Si MOSFET and that of the conventional RF component, is currently a focus of the manufacturers.

### SUMMARY

Therefore, an object of the disclosure is to provide a gallium nitride high electron mobility transistor and a method for manufacturing a gallium nitride high electron mobility transistor that can alleviate at least one of the drawbacks of the prior art.

According to a first aspect of the disclosure, the gallium nitride high electron mobility transistor includes a transistor structure, a heat dissipation structure for dissipating heat generated by the transistor structure, and at least one conductive structure. The transistor structure includes a composite semiconductor unit and an electrode unit disposed on the composite semiconductor unit. The composite semiconductor unit includes a gallium nitride layer. The electrode unit includes a gate electrode, a drain electrode, and a source electrode, and the drain electrode and the source electrode are disposed on opposite sides of the gate electrode. The heat dissipation structure includes a heat dissipation insulating layer connected to the composite semiconductor unit opposite to the electrode unit, and a heat dissipation metal unit disposed on the heat dissipation insulating layer away from the composite semiconductor unit. The heat dissipation metal unit includes a molybdenum substrate. The heat dissipation structure and the transistor structure cooperatively define at least one channel penetrating from a side of the heat dissipation insulating layer adjacent to the heat dissipation metal unit to the electrode unit. The at least one conductive structure is disposed in the at least one channel, and has two opposite ends respectively electrically connected to the heat dissipation metal unit and the electrode unit.

According to a second aspect of the disclosure, the method includes the steps of:
(a) attaching a temporary substrate to at least one transistor element which includes a sapphire substrate and a transistor structure, the transistor structure including a composite semiconductor unit disposed on the sapphire substrate, and an electrode unit disposed on the composite semiconductor unit opposite to the sapphire substrate, the composite semiconductor unit including a gallium nitride layer, the temporary substrate being attached to a side of the transistor structure away from the sapphire substrate, and then removing the sapphire substrate from the transistor structure;
(b) forming a heat dissipation insulating layer on the transistor structure opposite to the temporary substrate;
(c) etching the heat dissipation insulating layer from a side thereof away from the temporary substrate, so as to form at least one channel penetrating from the side of the heat dissipation insulating layer to the electrode unit;
(d) forming a conductive structure in the at least one channel so that the conductive structure is electrically connected to the electrode unit; and
(e) forming a heat dissipation metal unit on the side of the heat dissipation insulating layer away from the temporary substrate, followed by removing the temporary substrate, thereby obtaining the gallium nitride high electron mobility transistor, the heat dissipation metal unit being electrically connected to the conductive structure, and including a molybdenum substrate.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic view illustrating an embodiment of a gallium nitride high electron mobility transistor according to the disclosure.

FIG. 2 is a schematic top view illustrating a first implementation of the embodiment according to the disclosure.

FIG. 3 is a cross-sectional view of the embodiment shown in FIG. 2 taken along line III-III.

FIG. 4 is a schematic top view illustrating a second implementation of the embodiment according to the disclosure.

FIG. 5 is a cross-sectional view of the embodiment shown in FIG. 4 taken along line V-V.

FIG. 6 is a schematic top view illustrating a third implementation of the embodiment according to the disclosure.

FIG. 7 is a cross-sectional view of the embodiment shown in FIG. 6 taken along line XII-XII.

FIG. 8 is a flow diagram showing an embodiment of a method for manufacturing the embodiment of the gallium nitride high electron mobility transistor according to this disclosure.

FIG. 9 is a schematic cross-sectional view illustrating utilization of two transistor elements and a temporary substrate in the method for manufacturing the gallium nitride high electron mobility transistor of the embodiment.

FIG. 10 is a schematic cross-sectional view illustrating step (a) of the method.

FIG. 11 is a schematic cross-sectional view illustrating step (b) of the method.

FIG. 12 is a schematic cross-sectional view illustrating step (c) of the method.

FIG. 13 is a schematic cross-sectional view illustrating step (d) of the method.

FIG. 14 is a schematic cross-sectional view illustrating step (e) of the method.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

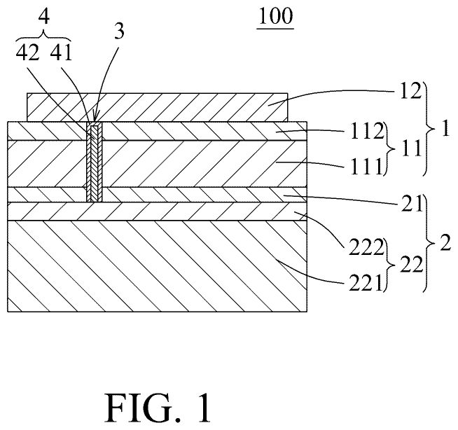

Referring to FIG. 1, an embodiment of a gallium nitride (GaN) high electron mobility transistor (HEMT) 100 according to the disclosure is provided. The GaN HEMT 100 includes a transistor structure 1, a heat dissipation structure 2, a channel 3, and a conductive structure 4. The transistor structure 1 is a horizontal power element, and includes a composite semiconductor unit 11 and an electrode unit 12 disposed on the composite semiconductor unit 11 (e.g., a front/upper surface of the composite semiconductor unit 11). The composite semiconductor unit 11 includes a GaN layer 111 and an isolation layer 112. The GaN layer 111 is made of GaN with a single-crystal structure, and is used to form a carrier channel (i.e., the channel 3). The isolation layer 112 is attached to a side of the GaN layer 111 adjacent to the electrode unit 12 (e. g., a front/upper surface of the GaN layer 111), and is provided to allow the electrode unit 12 to be disposed thereon. The isolation layer 112 is used to isolate the electrode unit 12 and the GaN layer 111, so that electrons in the GaN layer 111 can be driven by the electrode unit 12 to move, thereby forming an electric current or an electron flow. In this embodiment, the isolation layer 112 is made of aluminum gallium nitride (AlGaN), but other materials, such as a semiconductor material having a different energy gap from that of the GaN layer 111 can also be used for making the isolation layer 112, and hence are not limited to AlGaN.

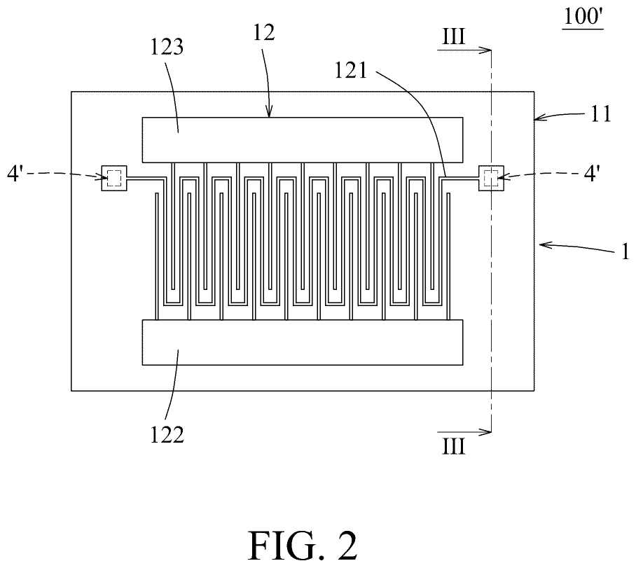

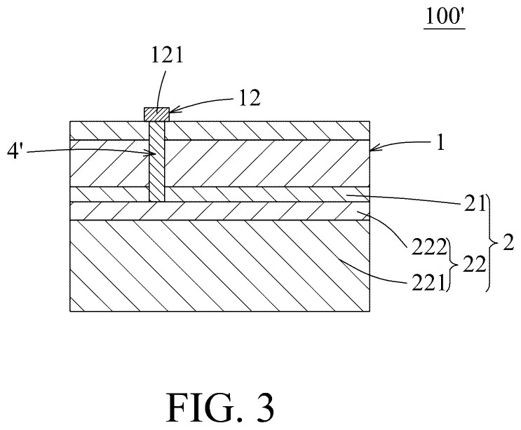

As shown in FIG. 1, the electrode unit 12 appears to be in a rectangular block shape, but referring to FIGS. 2 and 3, specifically, the electrode unit 12 includes a gate electrode 121, a drain electrode 122, and a source electrode 123, and the drain electrode 122 and the source electrode 123 are disposed on opposite sides of the gate electrode 121. When a voltage lower than a threshold voltage is applied to the gate electrode 121, a two-dimensional electron cloud in the GaN layer 111 located below the gate electrode 121 will be depleted, so that an open circuit is formed between the drain electrode 122 and the source electrode 123. In contrast, when a voltage higher than the threshold voltage is applied to the gate electrode 121, the two-dimensional electron cloud will be formed in the GaN layer 111 located below the gate electrode 121, so that a closed circuit is formed between the drain electrode 122 and the source electrode 123. In this embodiment, each of the drain electrode 122 and the source electrode 123 has a rectangular part and finger parts, and the finger parts of the drain electrode 122 and the finger parts of the source electrode 123 are staggered and spaced apart from each other to form an interdigitated pattern. The gate electrode 121 extends meanderingly along a space defined by the finger parts of the drain electrode 122 and the finger parts of the source electrode 123, and is spaced apart from the finger parts of the drain electrode 122 and the finger parts of the source electrode 123. The gate electrode 121 has a thickness less than a thickness of the rectangular part of the drain electrode 122 and a thickness of the rectangular part of the source electrode 123. However, the shape, thickness, and arrangement of the gate electrode 121, the drain electrode 122 and the source electrode 123 can be adjusted based on actual needs, and are not limited to the aforesaid description.

Referring to FIG. 1, the heat dissipation structure 2 is configured for dissipating heat generated by the transistor structure 1 outwardly by, e.g., radiation, and includes a heat dissipation insulating layer 21 connected to the composite semiconductor unit 11 opposite to the electrode unit 12 (e.g., a back/lower surface of the composite semiconductor unit 11), and a heat dissipation metal unit 22 disposed on the heat dissipation insulating layer 21 away from the composite semiconductor unit 11 (e.g., a back/lower surface of the heat dissipation insulating layer 21). The heat dissipation insulating layer 21 can be used to prevent electrical conduction between the GaN layer 111 and the heat dissipation metal unit 22, and to conduct the heat generated during operation of the transistor structure 1 to the heat dissipation metal unit 22, or to radiate the heat out to an external environment.

In this embodiment, a material of the heat dissipation insulating layer 21 may be aluminum nitride (AIN), boron nitride (BN), diamond-like carbon, or silicon carbide (SiC). AIN has a low cost, and possesses the characteristics of a wide energy gap (Eg=6.2 eV), an adequate dielectric strength (12.5 MV/cm), and a high thermal conductivity coefficient (3.21 W/cmK), which allow the heat dissipation insulating layer 21 to have effective insulating capacity and good heat dissipation property. Moreover, by using AlN as a material of the heat dissipation insulating layer 21, the GaN HEMT 100 may attain a breakdown voltage ranging from 650 V to 1200 V when the heat dissipation insulating layer 21 merely has a thickness ranging from 0.5 μm to 12 μm, which allows the heat dissipation insulating layer 21 to be thin enough to facilitate heat dissipation.

Referring to FIG. 1, the heat dissipation metal unit 22 is used to provide support for the transistor structure 1, so as to prevent the transistor structure 1 from breaking, and is capable of radiating the heat that is from the heat dissipation insulating layer 21 and that is generated by the operation of the transistor structure 1 out to the external environment. Specifically, the heat dissipation metal unit 22 includes a molybdenum substrate 221 and a metal bonding layer 222 disposed between the molybdenum substrate 221 and the heat dissipation insulating layer 21. The metal bonding layer 222 is used to bond the molybdenum substrate 221 to the heat dissipation insulating layer 21. In this embodiment, the metal bonding layer 222 is formed by plating a metal layer on a surface of each of the molybdenum substrate 221 and the heat dissipation insulating layer 21, followed by processing the aforesaid two metal layers at high temperature and high pressure (i.e., a metal pressing process), so as to obtain a surface bonding structure (i.e., the metal bonding layer 222) formed after atomic diffusion (diffusion bonding). Nevertheless, in other embodiments, the metal bonding layer 222 may be formed by a bonding agent such as a conductive glue.

Referring to FIG. 1, the molybdenum substrate 221 is made of molybdenum (Mo), and hence has a thermal expansion coefficient (5.3×10⁻⁶
) that approaches a thermal expansion coefficient (5.5×10⁻⁶
) of the GaN layer 111, and has a thermal conductivity coefficient (1.38 W/cmK) that is higher than a thermal conductivity coefficient (0.47 W/cmK) of sapphire. Therefore, the heat dissipation metal unit 22 has a better heat dissipation property compared with a sapphire substrate. As mentioned above, when the transistor structure 1 operates and generates the heat, such heat may be absorbed by the heat dissipation metal unit 22. Since the thermal expansion coefficient of the GaN layer 111 of the transistor structure 1 and the thermal expansion coefficient of the molybdenum substrate 221 are close, a volume change of the GaN layer 111 and a volume change of the molybdenum substrate 221 due to thermal expansion will not be greatly different, so deformation and breakage of the GaN layer 111 and the molybdenum substrate 221 caused by stress may be avoided.

Referring to FIG. 1, the heat dissipation structure 2 and the transistor structure 1 cooperatively define the channel 3 penetrating from a side of the heat dissipation insulating layer 21 adjacent to the heat dissipation metal unit 22 (e.g., the back/lower surface of the heat dissipation insulating layer 21) to a side of the electrode unit 12 adjacent to the composite semiconductor unit 11. In this embodiment, the channel 3 penetrates, from bottom to top, the heat dissipation insulating layer 21, the GaN layer 111, and the isolation layer 112, so that openings at both ends of the channel 3 are formed at the lower surface of the heat dissipation insulating layer 21 and an upper surface of the isolation layer portion 112, respectively.

Referring to FIG. 1, the conductive structure 4 is disposed in the channel 3, and has two opposite ends respectively electrically connected to the heat dissipation metal unit 22 and the electrode unit 12. In this embodiment, the conductive structure 4 includes a seed layer 41 bonded to a channel-defining wall that defines the channel 3, and a conductive body 42 bonded to the seed layer 41 and filling the channel 3. The seed layer 41 allows the conductive structure 4 to be firmly bonded to the channel-defining wall. The conductive body 42 is made of gold or copper, which allows the conductive structure 4 to have good conductivity.

However, other conductive materials may be used to make the conductive structure 4, and hence are not limited to gold or copper. In addition, the number of the conductive structure(s) 4 and the number of the channel(s) 3 are identical, and each may be one or more depending on actual requirements.

FIGS. 2 and 3 show a first implementation of this embodiment. In the first implementation, the GaN HEMT 100′ has two of the conductive structures 4′. As shown in FIG. 2, the conductive structures 4′ are respectively electrically connected to two ends of the gate electrode 121, and as shown in FIG. 3, the two opposite ends of each of the conductive structures 4′ are electrically connected to the heat dissipation metal unit 22 and the gate electrode 121, respectively. In this way, the gate electrode 121 and the heat dissipation metal unit 22 can be electrically connected through the conductive structures 4′, and the gate electrode 121 can be used as a grounding structure, thereby reducing parasitic inductance caused by grounding of the gate electrode 121.

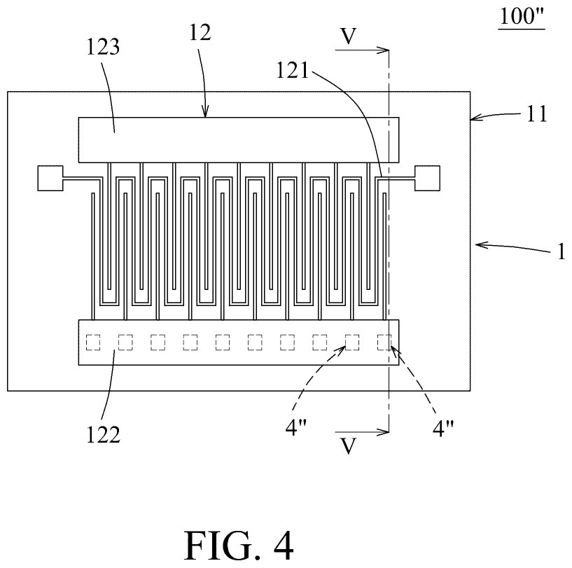

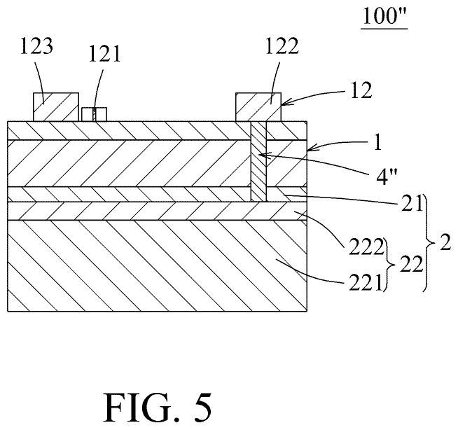

FIGS. 4 and 5 provide a second implementation of this embodiment. In the second implementation, the GaN HEMT 100″ has ten of the conductive structures 4″. As shown in FIG. 4, the conductive structures 4″ are arranged at intervals along a length direction of the rectangular part of the drain electrode 122, and as shown in FIG. 5, the two opposite ends of each of the conductive structures 4″ are electrically connected to the heat dissipation metal unit 22 and the drain electrode 122, respectively. In this way, the drain electrode 122 and the heat dissipation metal unit 22 can be electrically connected through the conductive structures 4″, so as to allow the GaN HEMT 100″ to be structurally similar to a vertical power transistor (e.g., a Si metal-oxide-semiconductor field-effect transistor (Si-MOSFET)), thereby resolving a parasitic inductance problem caused by wiring.

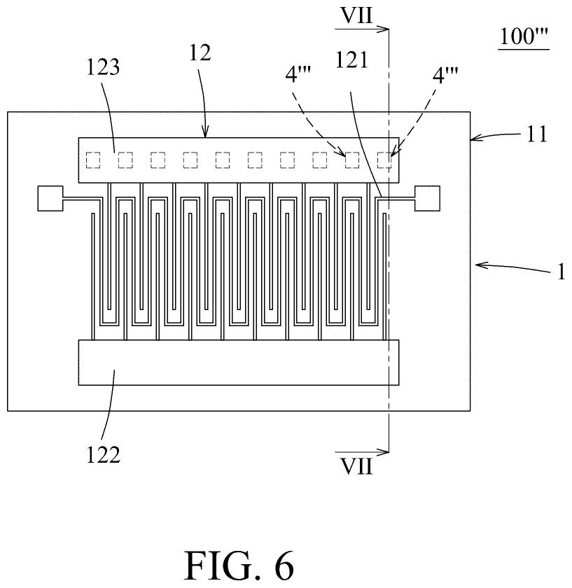

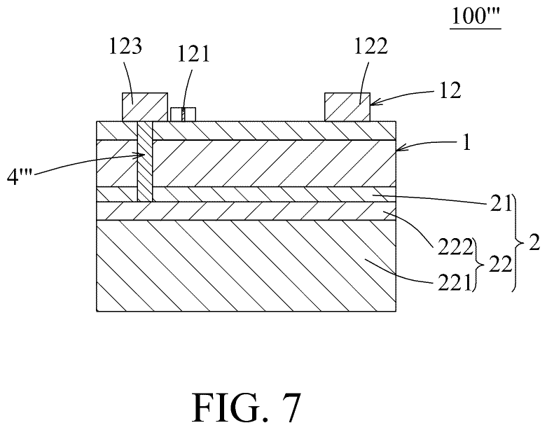

FIGS. 6 and 7 provide a third implementation of this embodiment. In the third implementation, the GaN HEMT 100′″ has ten of the conductive structures 4′″. As shown in FIG. 6, the conductive structures 4′″ are arranged at intervals along a length direction of the rectangular part of the source electrode 123, and as shown in FIG. 7, the two opposite ends of each of the conductive structures 4′″ are electrically connected to the heat dissipation metal unit 22 and the source electrode 123, respectively. In this way, the source electrode 123 and the heat dissipation metal unit 22 can be electrically connected through the conductive structures 4′″, thereby resolving the parasitic inductance problem caused by wiring, and hence increasing the operating speed of the transistor structure 1 as well as reducing heat generation.

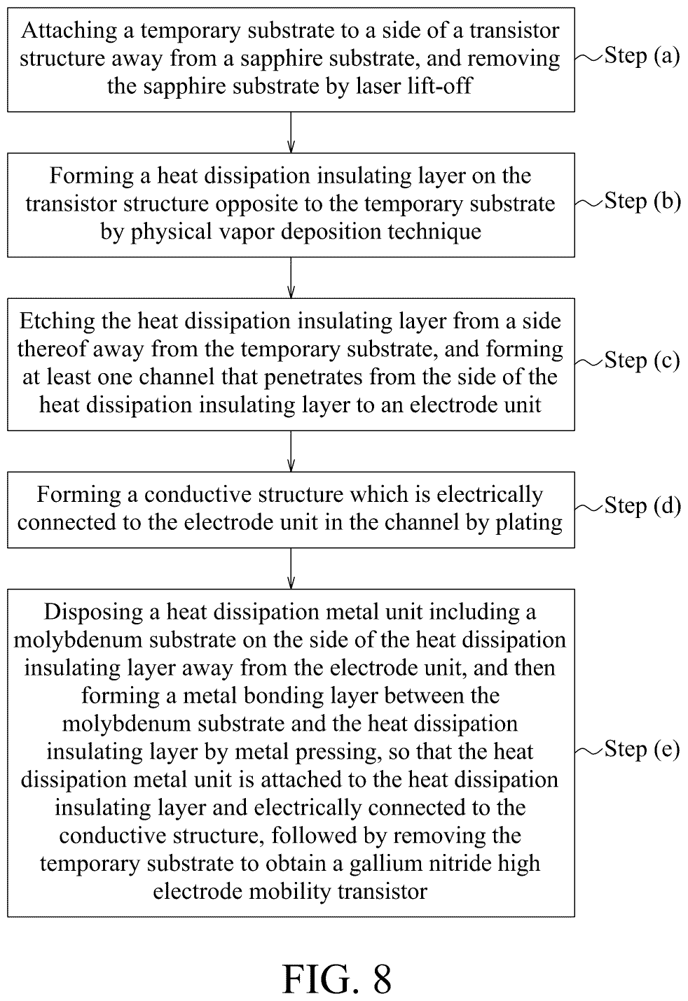

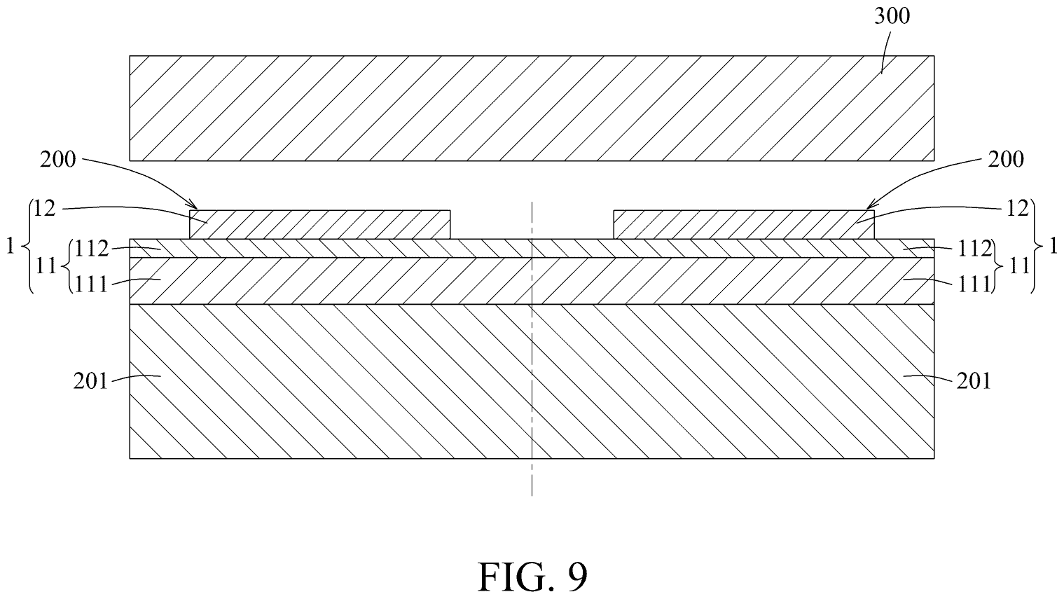

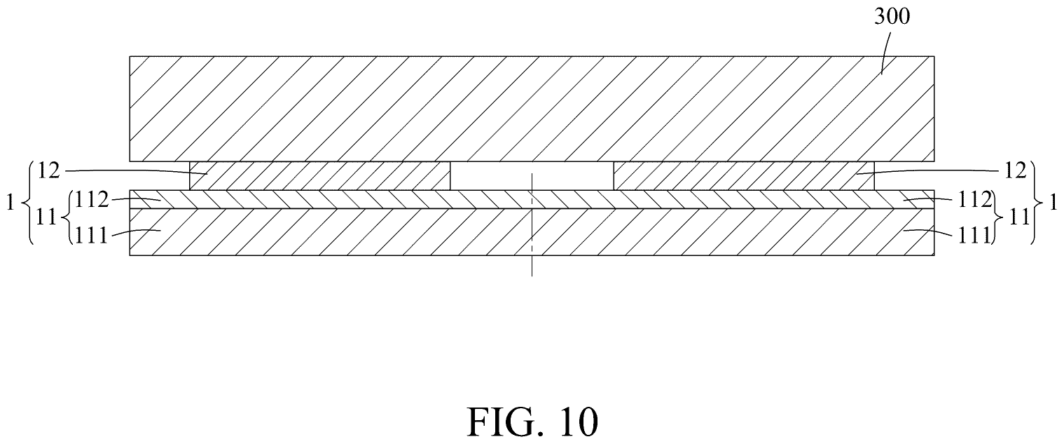

FIG. 8 shows an embodiment of a method for manufacturing the GaN HEMT 100 according to this disclosure. The method will be described in detail below with reference to FIGS. 9 to 14. As shown in FIG. 9, in this embodiment, the method is carried out using at least one transistor element 200 and a temporary substrate 300 for temporarily supporting the transistor element 200. For convenience of description, in this embodiment, two of the transistor elements 200 (separated by a dotted chain line as shown in FIG. 9) are used as an example to illustrate how multiple of the transistor elements 200 are processed at one time in a practical situation. However, the method can also be implemented using one, three or more of the transistor elements 200, and the transistor elements 200 can be arranged in any manner based on actual needs.

Referring to FIGS. 8 and 9, each of the transistor elements 200 includes a sapphire substrate 201 and the aforesaid transistor structure 1. The transistor structure 1 includes the composite semiconductor unit 11 disposed on the sapphire substrate 201, and the electrode unit 12 disposed on the composite semiconductor unit 11 opposite to the sapphire substrate 201. In this method, the sapphire substrates 201 of the transistor elements 200 are connected to each other and integrally formed. Moreover, the GaN layers 111 of the composite semiconductor units 11 of the transistor structures 1 of the transistor elements 200 are connected to each other and integrally formed, and the isolation layers 112 of the composite semiconductor units 11 are also connected to each other and integrally formed. Additionally, the electrode units 12 of the transistor structures 1 of the transistor elements 200 are patterned and hence separated from each other. Referring to FIG. 9, the temporary substrate 300 has a shape of a rectangle, so the temporary substrate 300 may correspond to the electrode units 12, each of which is illustrated as a rectangular block as shown in FIG. 1. Nevertheless, referring to FIG. 3, in actual implementation, the contour of a side surface of the temporary substrate 300 facing toward the transistor structures 1 should be in a concave and convex form (not shown) to correspond to a surface topography of each of the electrode units 12, so that the temporary substrate 300 is capable of attaching to the electrode units 12 of the transistor structures 1. Alternatively, the side surface of the temporary substrate 300 may elastically deform in response to the surface topography of the electrode units 12, so as to allow the temporary substrate 300 to be attached to the electrode units 12 of the transistor structures 1.

Referring to FIGS. 8 to 10, initially, in step (a), the temporary substrate 300 is attached to a side of the transistor structures 1 away from the sapphire substrates 201, and then the sapphire substrates 201 that are integrally formed are removed from the transistor structures 1. Specifically, the temporary substrate 300 is adhered to the transistor structures 1 with an adhesive. In addition, the sapphire substrates 201 that are integrally formed are removed by laser lift-off.

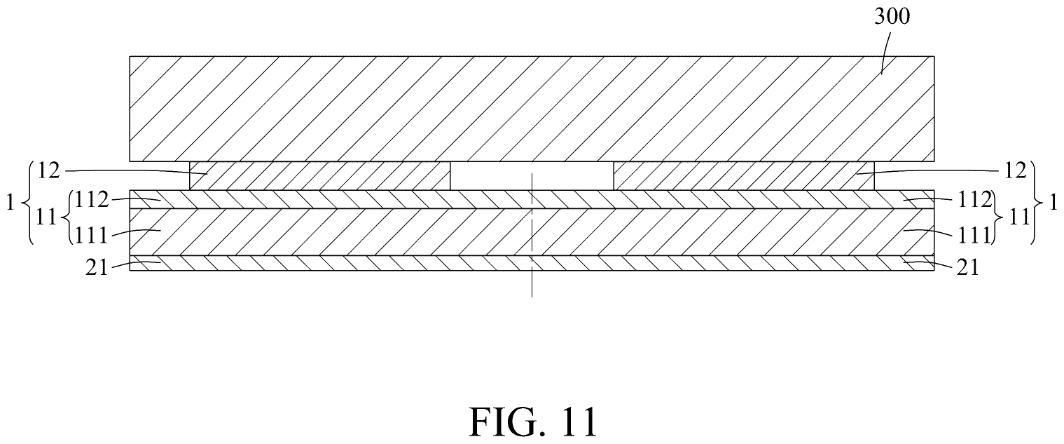

Referring to FIGS. 8 and 11, in step (b), the heat dissipation insulating layer 21 is formed on each of the transistor structures 1 opposite to the temporary substrate 300. To be specific, a thin film structure is deposited on a side of the transistor structures 1 opposite to the temporary substrate 300 by physical vapor deposition technique, thereby obtaining the heat dissipation insulating layers 21 that are connected to each other and formed integrally. In addition, a material of the heat dissipation insulating layers 21 may be AlN, BN, diamond-like carbon, or SiC.

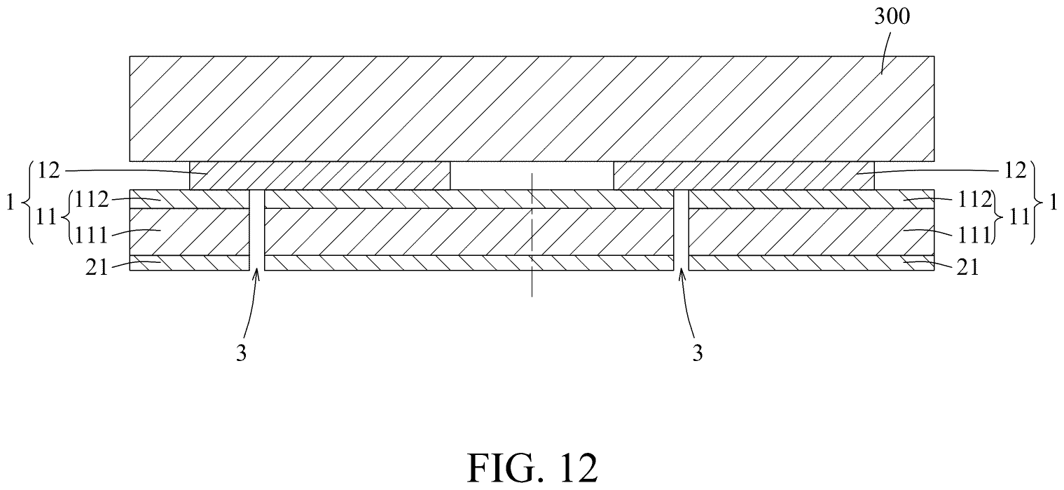

Referring to FIGS. 8 and 12, in step (c), by etching each of the heat dissipation insulating layers 21 from a side thereof away from the temporary substrate 300, the at least one channel 3 that penetrates from the side of each of the heat dissipation insulating layers 21 to a corresponding one of the electrode units 12 adjacent to a side of the composite semiconductor unit 11 is formed. Specifically, the at least one channel 3 may be formed by anisotropic etching, such as plasma etching. In the method for manufacturing the GaN HEMT 100 of this embodiment, the position and number of the channel(s) 3 formed in each of the heat dissipation insulating layers 21 may be adjusted depending on actual needs. For example, the number of the channel(s) 3 formed in each of the heat dissipation insulating layers 21 is two, and the two channels 3 are respectively aligned in position with the two ends of the gate electrode 121 of a corresponding one of the transistor structures 1. Alternatively, the number of the channel(s) 3 formed in each of the heat dissipation insulating layers 21 may be ten, and the ten channel(s) 3 are aligned in position along the drain electrode 122 or the source electrode 123 of the corresponding one of the transistor structures 1.

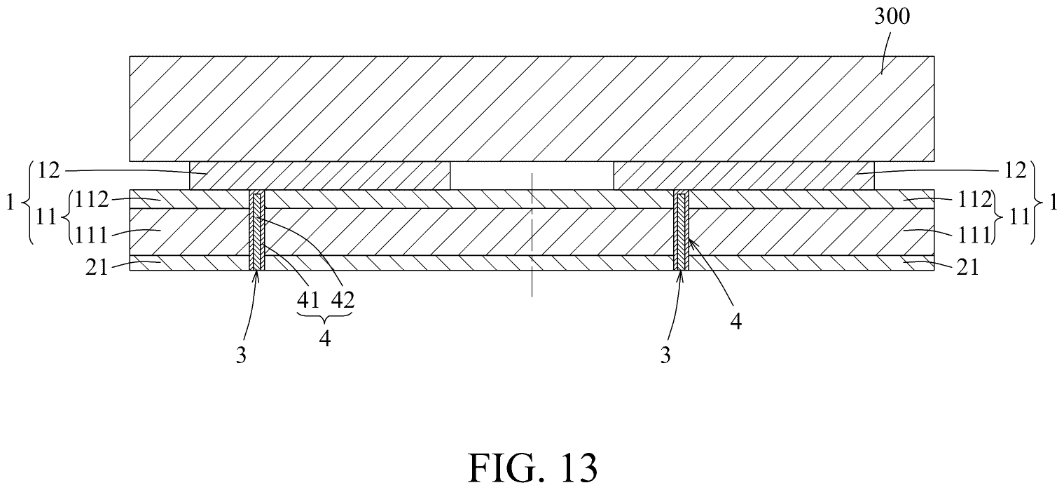

Referring to FIGS. 8 and 13, in step (d), in each of the channel(s) 3, the conductive structure 4 electrically connected to a corresponding one of the electrode units 12 is formed by plating. Specifically, in step (d), for each of the channels 3, the seed layer 41 may be initially plated on the channel-defining wall as well as a surface portion of the temporary substrate 300 which is exposed from the channel. Subsequently, gold is plated on the seed layer 41, and fills the channel 3, so as to form the conductive body 42 on the seed layer 41, thereby obtaining the conductive structures 4. However, in step (d), gold or copper may be directly plated in each of the channels 3 and on the side of each of the heat dissipation insulating layers 21 away from the electrode units 12 by electroplating or chemical plating, so that a gold structure or a copper structure located in and filling each of the channels 3 obtained thereby is formed into the conductive structure 4, which is electrically connected to a corresponding one of the electrode units 12. The gold or copper located on the side of each of the heat dissipation insulating layers 21 can be used in the metal pressing process performed subsequently.

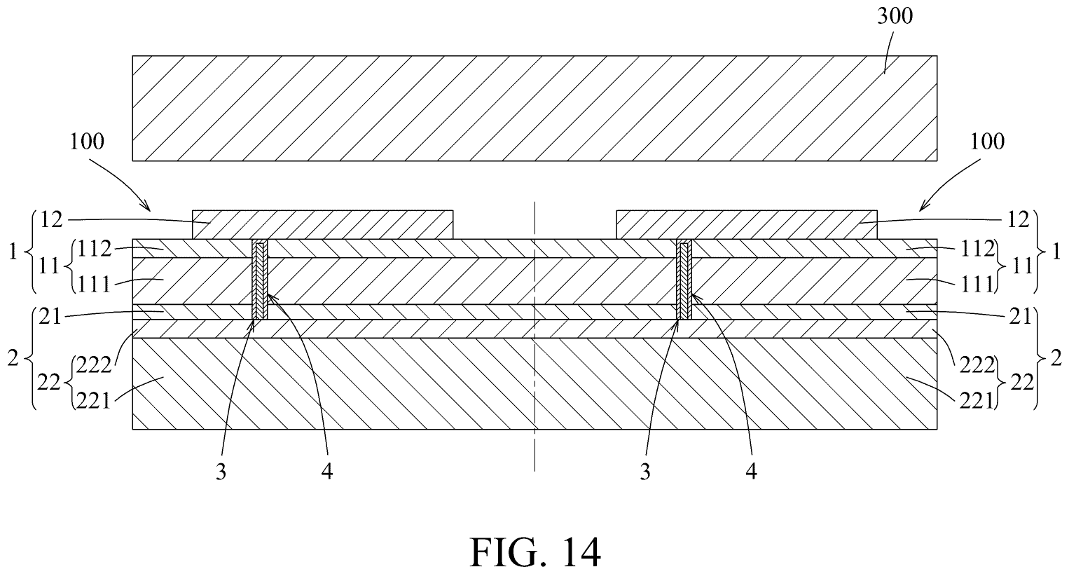

Referring to FIGS. 8 and 14, in step (e), at first, the heat dissipation metal units 22 that are formed integrally, are formed on the side of the heat dissipation insulating layers 21, which are also integrally formed, away from the electrode units 12. Each of the heat dissipation metal units 22 is electrically connected to a corresponding one of the conductive structures 4, and includes the molybdenum substrate 221. Specifically, each of the molybdenum substrates 221 with the metal layer which is plated on the surface thereof is first placed on the side of a corresponding one of the heat dissipation insulating layers 21 away from the electrode units 12 with the metal layer on the molybdenum substrate 221 facing the corresponding one of the heat dissipation insulating layers 21, followed by pressing each of the molybdenum substrates 221 and the corresponding one of the heat dissipation insulating layers 21 at high temperature and high pressure (i.e., the aforesaid metal pressing process), so that the gold or copper located on the side of each of the heat dissipation insulating layers 21 away from the electrode units 12 and the metal layer plated on the surface of the molybdenum substrate 221 form into the metal bonding layer 222 after the atomic diffusion, and that the metal bonding layer 222 is disposed between each of the molybdenum substrates 221 and the corresponding one of the heat dissipation insulating layers 21, thereby allowing each of the heat dissipation metal units 22 to be attached to a corresponding one of the heat dissipation insulating layers 21. Alternatively, the conductive glue may be used as the metal bonding layer 222 to connect each of the molybdenum substrates 221 and the corresponding one of the heat dissipation insulating layers 21. Next, the temporary substrate 300 is removed, so that the transistor structures 1 are supported by the heat dissipation metal units 22 that are integrally formed. Finally, the GaN layers 111 that are formed integrally, the isolation layers 112 that are formed integrally, the heat dissipation insulating layers 21 that are formed integrally, and the heat dissipation metal units 22 that are formed integrally, are subjected to knife cutting or laser cutting from their connection sites (i.e., along a dotted chain line as shown in FIG. 14), so as to obtain two of the GaN HEMTs 100.

It is noteworthy that the method can also be implemented by using a single one of the transistor elements 200 and the temporary substrate 300. In this way, in step (e), cutting of the GaN layers 111, the isolation layers 112, the heat dissipation insulating layers 21, and the heat dissipation metal units 22 can be omitted.

To sum up, by disposing the transistor structure 1 on the molybdenum substrate 221 whose thermal conductivity is higher than that of sapphire, heat generated during operation of the transistor structure 1 can be quickly dissipated, e.g., by radiation, outwardly via the molybdenum substrate 221, thereby improving the effect of heat dissipation. In addition, by disposing the transistor structure 1 on the molybdenum substrate 221 whose thermal expansion coefficient is close to that of the GaN layer 111, a difference in volume change between the GaN layer 111 and the molybdenum substrate 221 due to thermal expansion may be reduced, so as to avoid deformation or fracture caused by stress, thereby enhancing the durability of the GaN HEMT 100. Furthermore, by allowing the two opposite ends of the conductive structure 4 to be respectively electrically connected to the heat dissipation metal unit 22 and the source electrode 123, or to be respectively electrically connected to the heat dissipation metal unit 22 and the drain electrode 122, the source electrode 123 or the drain electrode 122 may be guided to a side (e.g., a backside of the GaN HEMT 100) away from electrode unit 12, so that the GaN HEMT 100 may be applied to a conventional packaging process, thereby reducing costs and hence achieving the purpose of the present invention.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A gallium nitride high electron mobility transistor, comprising:
a transistor structure including a composite semiconductor unit and an electrode unit disposed on the said composite semiconductor unit, said composite semiconductor unit including a gallium nitride layer, said electrode unit including a gate electrode, a drain electrode, and a source electrode, said drain electrode and said source electrode being disposed on opposite sides of said gate electrode;
a heat dissipation structure for dissipating heat generated by said transistor structure, and including a heat dissipation insulating layer connected to said composite semiconductor unit opposite to said electrode unit, and a heat dissipation metal unit disposed on said heat dissipation insulating layer away from said composite semiconductor unit, said heat dissipation metal unit including a molybdenum substrate, said heat dissipation structure and said transistor structure cooperatively defining at least one channel penetrating from a side of said heat dissipation insulating layer adjacent to said heat dissipation metal unit to said electrode unit; and
at least one conductive structure disposed in said at least one channel, and having two opposite ends respectively electrically connected to said heat dissipation metal unit and said electrode unit.

2. The gallium nitride high electron mobility transistor as claimed in claim 1, wherein a material of said heat dissipation insulating layer is aluminum nitride (AlN), boron nitride (BN), diamond-like carbon, or silicon carbide (SiC).

3. The gallium nitride high electron mobility transistor as claimed in claim 1, wherein said heat dissipation insulating layer has a thickness ranging from 0.5 μm to 12 μm.

4. The gallium nitride high electron mobility transistor as claimed in claim 1, wherein said two opposite ends of said at least one conductive structure are respectively electrically connected to said heat dissipation metal unit and said gate electrode of said electrode unit.

5. The gallium nitride high electron mobility transistor as claimed in claim 1, wherein said two opposite ends of said at least one conductive structure are respectively electrically connected to said heat dissipation metal unit and said source electrode of said electrode unit.

6. The gallium nitride high electron mobility transistor as claimed in claim 1, wherein said two opposite ends of said at least one conductive structure are respectively electrically connected to said heat dissipation metal unit and said drain electrode of said electrode unit.

7. The gallium nitride high electron mobility transistor as claimed in claim 1, wherein said heat dissipation metal unit further includes a metal bonding layer disposed between said molybdenum substrate and said heat dissipation insulating layer.

8. The gallium nitride high electron mobility transistor as claimed in claim 1, wherein said composite semiconductor unit of said transistor structure further includes an isolation layer attached to a side of said gallium nitride layer adjacent to said electrode unit.

9. The gallium nitride high electron mobility transistor as claimed in claim 1, wherein said at least one conductive structure includes a seed layer bonded to a channel-defining wall defining said at least one channel, and a conductive body bonded to said seed layer and filling said at least one channel.

10. A method for manufacturing a gallium nitride high electron mobility transistor, comprising the steps of:
(a) attaching a temporary substrate to at least one transistor element which includes a sapphire substrate and a transistor structure, the transistor structure including a composite semiconductor unit disposed on the sapphire substrate, and an electrode unit disposed on the composite semiconductor unit opposite to the sapphire substrate, the composite semiconductor unit including a gallium nitride layer, the temporary substrate being attached to a side of the transistor structure away from the sapphire substrate, and then removing the sapphire substrate from the transistor structure;
(b) forming a heat dissipation insulating layer on the transistor structure opposite to the temporary substrate;
(c) etching the heat dissipation insulating layer from a side thereof away from the temporary substrate, so as to form at least one channel penetrating from the side of the heat dissipation insulating layer to the electrode unit;
(d) forming a conductive structure in the at least one channel so that the conductive structure is electrically connected to the electrode unit; and
(e) forming a heat dissipation metal unit on the side of the heat dissipation insulating layer away from the electrode unit, followed by removing the temporary substrate, thereby obtaining the gallium nitride high electron mobility transistor, the heat dissipation metal unit being electrically connected to the conductive structure, and including a molybdenum substrate.

11. The method as claimed in claim 10, wherein in step (a), removing of the sapphire substrate is performed by laser lift-off.

12. The method as claimed in claim 10, wherein step (b) is conducted using physical vapor deposition technique, a material of the heat dissipation insulating layer being AIN, BN, diamond-like carbon, or SiC.

13. The method as claimed in claim 10, wherein in step (e), the heat dissipation metal unit further includes a metal bonding layer disposed between the molybdenum substrate and the heat dissipation insulating layer, so that the heat dissipation metal plate is attached to the heat dissipation insulating layer.

14. The method as claimed in claim 13, wherein the metal bonding layer is formed by a metal pressing process.

15. The method as claimed in claim 13, wherein the metal bonding layer is a conductive glue.

16. The method as claimed in claim 10, wherein step (d) includes forming a seed layer on a channel-defining wall defining the at least one channel, forming a conductive body on the seed layer, and filling the at least one channel with the conductive body.

17. The method as claimed in claim 10, wherein the composite semiconductor unit further includes an isolation layer attached to a side of the gallium nitride layer adjacent to the electrode unit.
